(19) United States
(12) Patent Application Publication
(10) Pub. No.: US 2015/0137229 A1
(43) Pub. Date: May 21, 2015

(54) SEMICONDUCTOR DEVICE AND METHOD FOR FABRICATING THE SAME

(71) Applicant: Vanguard International Semiconductor Corporation, Hsinchu (TW)

(72) Inventors: Priyono Tri SULISTYANTO, Umbulharjo (ID); Shang-Hui TU, Jhubei City (TW)

(73) Assignee: Vanguard International Semiconductor Corporation, Hsinchu (TW)

(21) Appl. No.: 14/081,580

(22) Filed: Nov. 15, 2013

(51) Int. Cl. H01L 29/78; H01L 29/06; H01L 29/10; H01L 29/66

(52) U.S. Cl. CPC H01L 29/7816; H01L 29/66681; H01L 29/063; H01L 29/1095
USPC 257/339; 438/286

(57) ABSTRACT

The invention provides a semiconductor device, including: a substrate having a first conductivity type, including: a body region having the first conductivity type; a source region formed in the body region; a drift region having a second conductivity type adjacent to the body region, wherein the first conductivity type is opposite to the second conductivity type; and a drain region formed in the drift region; a multiple reduced surface field (RESURF) structure embedded in the drift region of the substrate; and a gate dielectric layer having a thick portion formed over the substrate, wherein the gate dielectric includes at least a stepped-shape or a curved shape curved-shape formed thereon, and wherein the multiple RESURF structure is aligned with the thick portion of the gate dielectric layer.

### BACKGROUND OF THE INVENTION

1. Field of the Invention

The present invention relates to a semiconductor device, and in particular, relates to a semiconductor device having high breakdown voltage as well as very low on-resistance and a method for fabricating the same.

2. Description of the Related Art

Bipolar-CMOS-LDMOSs (BCDs) have been widely used in power management integrated circuits (PMIC). BCD technology integrates bipolar, complementary metal-oxide-semiconductor (CMOS) and laterally diffused metal-oxide-semiconductor (LDMOS) technology into one chip. In a BCD device, a bipolar device is used to drive high currents, a CMOS provides low power consumption for digital circuits, and an LDMOS device provides high voltage (HV) handling capabilities.

LDMOS devices are widely used in various applications. On-resistance is an important factor that is directly proportional to the power consumption of an LDMOS device. As the demand for power savings and better performance of electronic devices increase, manufacturers have continuously sought to reduce the leakage and on-resistance (Rₒₙ) of LDMOS devices. However, the reduction of on-resistance is closely related to the high off-state breakdown voltage. Specifically, reducing the on-resistance leads to a substantial drop in the high off-state breakdown voltage. Thus, a conventional LDMOS device is able to deliver high off-state breakdown voltage but fails to provide low on-resistance.

An LDMOS device includes a drift region, and a body region. It has been observed that the on-resistance of the conventional LDMOS device decreases when the dopant concentration of the drift region increases. However, the high off-state breakdown voltage of the LDMOS decreases as the doping concentration increases.

Thus, an improved semiconductor device having low on-resistance without the deficiencies related to the breakdown voltage and a method for fabricating the same are needed.

### BRIEF SUMMARY OF THE INVENTION

An exemplary embodiment of a semiconductor device including: a substrate having a first conductivity type, including: a body region having the first conductivity type; a source region formed in the body region; a drift region having a second conductivity type adjacent to the body region, wherein the first conductivity type is opposite to the second conductivity type; and a drain region formed in the drift region; a multiple reduced surface field (RESURF) structure embedded in the drift region of the substrate; and a gate dielectric layer having a thick portion formed over the substrate, wherein the gate dielectric includes at least a stepped-shape or a curved shape curved-shape formed thereon, and wherein the multiple RESURF structure is aligned with the thick portion of the gate dielectric layer.

An exemplary embodiment of a method for fabricating a semiconductor device includes: providing a semiconductor substrate having a first conductivity type; forming a body region having the first conductivity type in the substrate and a drift region having a second conductivity type adjacent to the body region, wherein the first conductivity type is opposite to the second conductivity type; forming a first dielectric layer over the substrate; forming a mask layer over the first dielectric layer, wherein the mask layer has an opening exposing a portion of the first dielectric layer; performing an ion implantation process through the opening to form a multiple reduced surface field (RESURF) structure in the drift region; forming a second dielectric layer over the portion of the first dielectric layer in the opening, wherein the second dielectric layer is thicker than the first dielectric layer and wherein the multiple RESURF structure is aligned with the second dielectric layer; removing the mask layer; removing another portion of the first dielectric layer, wherein the remaining portion of the first dielectric layer associates with the second dielectric layer to form a multiple dielectric structure, wherein the multiple dielectric structure comprises at least a stepped-shape or a curved-shape formed thereon; applying a thermal oxidation to the multiple dielectric structure to define the multiple dielectric structure as a gate dielectric layer; forming a source region in the body region and a drain region in the drift region; and forming a gate electrode over the gate dielectric layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is cross-sectional view of a conventional semiconductor device; and

FIGS. 2a-8 are cross-sectional views illustrating a method for forming a semiconductor device in accordance with embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice the invention.

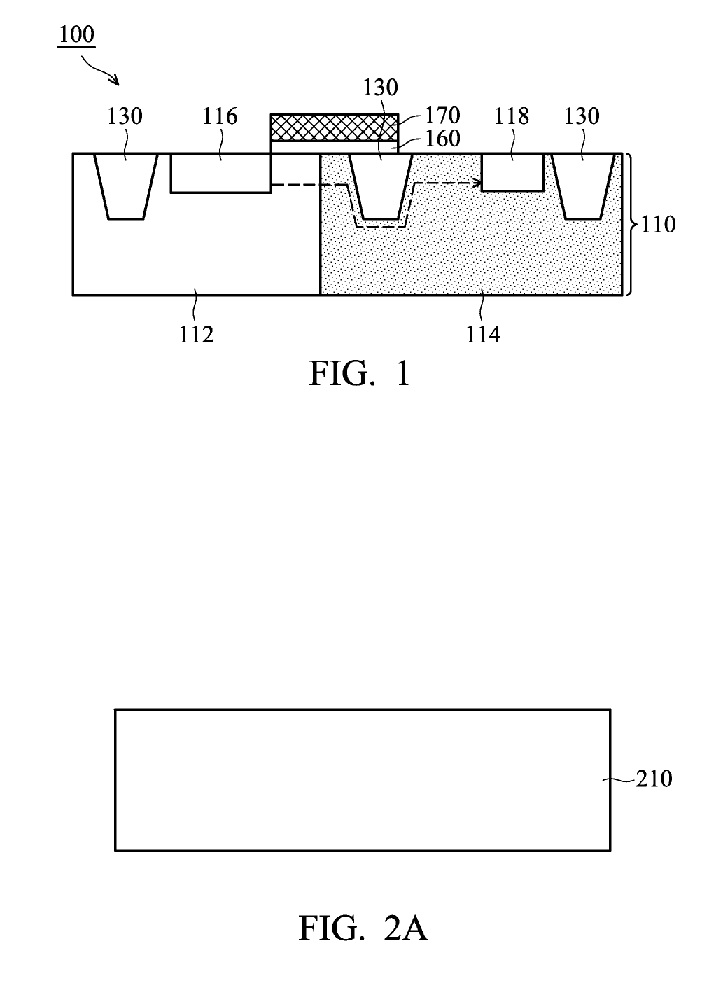

Referring to FIG. 1, a cross-sectional view of a conventional semiconductor device 100 is illustrated. The semiconductor device 100 comprises a substrate 110 having a body region 112 and a drift region 114 formed in the substrate 110. The substrate 110 further comprises a plurality of shallow trench isolations (STIs) 130 formed therein. In the semiconductor device 100, the current from the source region 116 to the drain region 118 flows by a devious path as shown as the dotted line in FIG. 1 due to the obstruction of the STI 130 in between the source and drain regions 116 and 118. The deviation of the current path results in a high on-resistance of the semiconductor device 100.

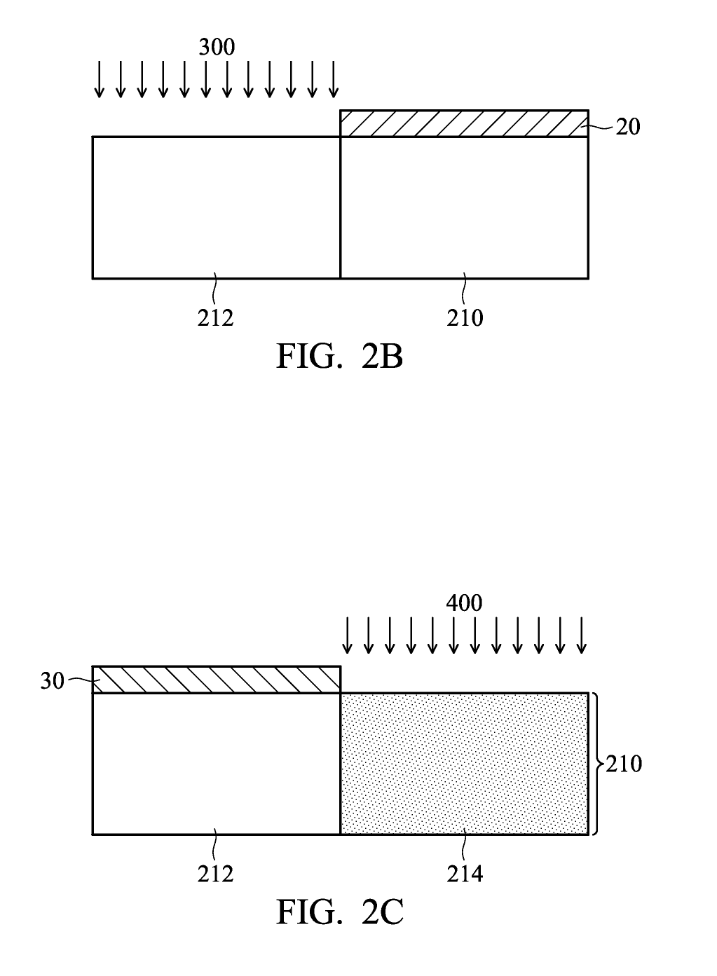

FIGS. 2-8 illustrate a step-by-step procedure for fabricating a semiconductor device 200 in accordance with embodiments of the present disclosure, in which FIGS. 2a-2c illustrate the formation of a body region and a drift region of the semiconductor device 200. Referring to FIG. 2a, a substrate 210 having a first conductivity type is provided. The substrate 210 may be a bulk silicon substrate, a silicon-on-insulator (SOI) substrate, or the like. In some embodiments, the substrate 210 may have a first conductivity type of p-type, such as a boron doped substrate. In other embodiments, the substrate 210 may have a first conductivity type of n-type, such as a phosphor or arsenic substrate. Any other suitable substrates may also be used.

Referring to FIG. 2b, a patterned mask layer 20 is formed over the substrate 210. The patterned mask layer 20 may be a photoresist layer or a hard mask layer such as a silicon nitride or a silicon oxynitride layer or the like. After the patterned mask layer 20 is formed, a doping process 300 is performed to selectively dope a dopant having a first conductivity type, into the semiconductor substrate 210 to define a body region 212. In some exemplary embodiments, the concentration of the substrate 210 may be greater than that of the body region 212. For example, when the body region 212 is p-type, the substrate 210 may be heavily doped p-type (P+). The mask layer 20 is then removed after the body region 212 is formed.

Referring to FIG. 2c, another patterned mask layer 30 is formed over the substrate 210. The patterned mask layer 30 may be a photoresist layer or a hard mask layer such as a silicon nitride or a silicon oxynitride layer or the like. A doping process 400 is performed to selectively dope a dopant having a second conductivity type, into the semiconductor substrate 210 to define a drift region 214. In some embodiments, the second conductivity type is different from the first conductivity type. The patterned mask layer 30 is removed once the drift region 214 is formed.

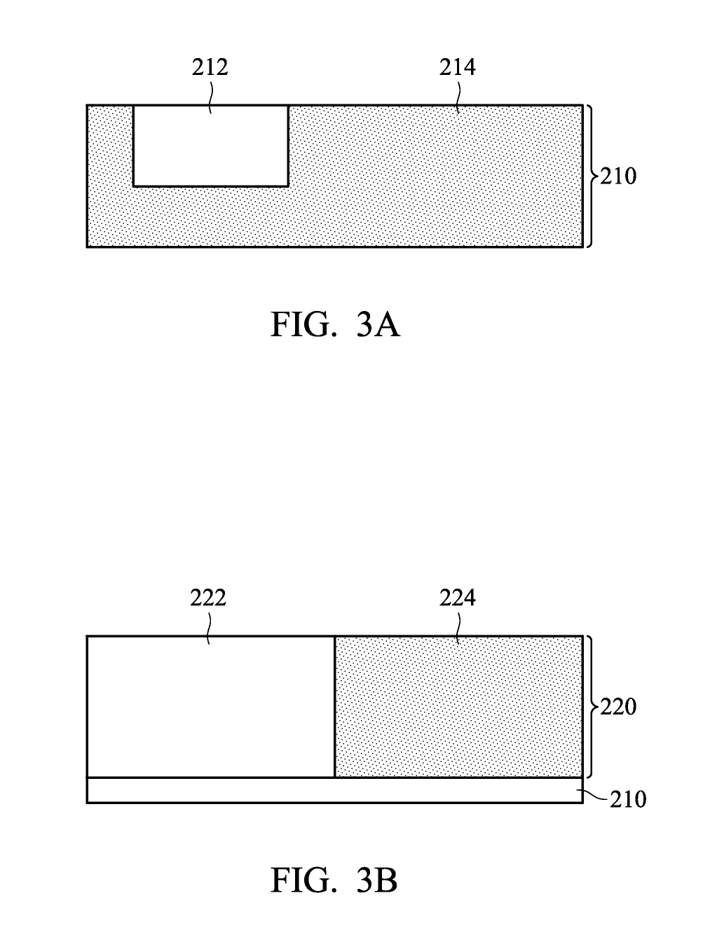

Referring to FIG. 3a, in another embodiment, the drift region 214 may be blanketly formed prior to the formation of the body region 212. After the drift region 214 is formed, the body region 212 is formed in the drift region by an implantation process.

In yet another embodiment, an epitaxial layer may be optionally formed over the substrate 210 and the body and drift regions are formed in the epitaxial layer. Referring to FIG. 3b, an epitaxial layer 220 having the first conductivity type is formed on the substrate 210. Moreover, the semiconductor substrate 210 has a doping concentration larger than that of the epitaxial layer 220. For example, when the first conductivity type is n-type, the semiconductor substrate 210 may be a heavily doped n-type (N+) semiconductor substrate 210, while the epitaxial layer 220 may be a lightly doped n-type (N−) epitaxial layer. The epitaxial layer 220 may be formed by epitaxial growth to a thickness ranging from 3 um to 10 um. In this embodiment, the body region 222 and the drift region 224 are formed in the epitaxial layer 220, and the formation body and drift regions 222 and 224 is similar to that of the body and drift regions 212 and 214, and hence is not discussed herein to avoid repetition.

After the body region 212 and the drift region 214 are formed, a procedure for forming a multiple reduced surface field (RESURF) structure and a gate dielectric layer is then performed.

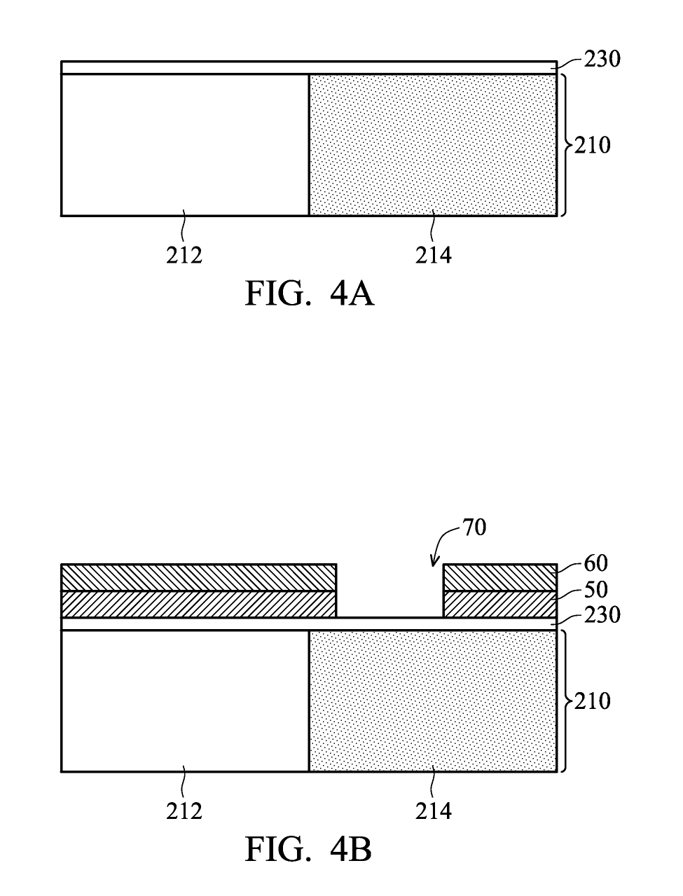

FIGS. 4a-4c illustrate the formation of a multiple reduced surface field (RESURF) structure and a gate dielectric layer on the structure of FIG. 2c. It will be appreciated, however, the same procedure is applicable to structures of FIG. 3a-3b. Referring to FIG. 4a, a first dielectric layer 230 is formed over the substrate 210 (or the epitaxial layer 220 if any). The first dielectric layer 230 comprises silicon oxide, silicon nitride, silicon oxynitride, high-k dielectrics, other suitable dielectric materials, or combinations thereof. High-k dielectrics may comprise metal oxides, for example, oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu and mixtures thereof. The first dielectric layer 230 may be formed by any process known in the art, such as atomic layer deposition (ALD), chemical vapor deposition (CVD), physical vapor deposition (PVD), thermal oxidation, UV-ozone oxidation, or combinations thereof. The first dielectric layer 230 may have a thickness from about 70 angstroms to 2000 angstroms

Referring to FIG. 4b, a first mask layer and a second mask layer 50 and 60 are sequentially formed over the first dielectric layer 230. The first mask layer 50 may be a hard mask comprising silicon nitride or silicon oxynitride and the second mask layer 60 may be a patterned photoresist. An opening 70 through the first and second mask layer 50 and 60 is formed, thereby exposes a portion of the first dielectric layer 230 to be defined as the multiple RESURF region. The opening 70 may be formed by an etching process.

Referring to 4c, a series of ion implantation processes 500 is performed to form a multiple RESURF structure 240 in the drift region 214 (or 224 if any).

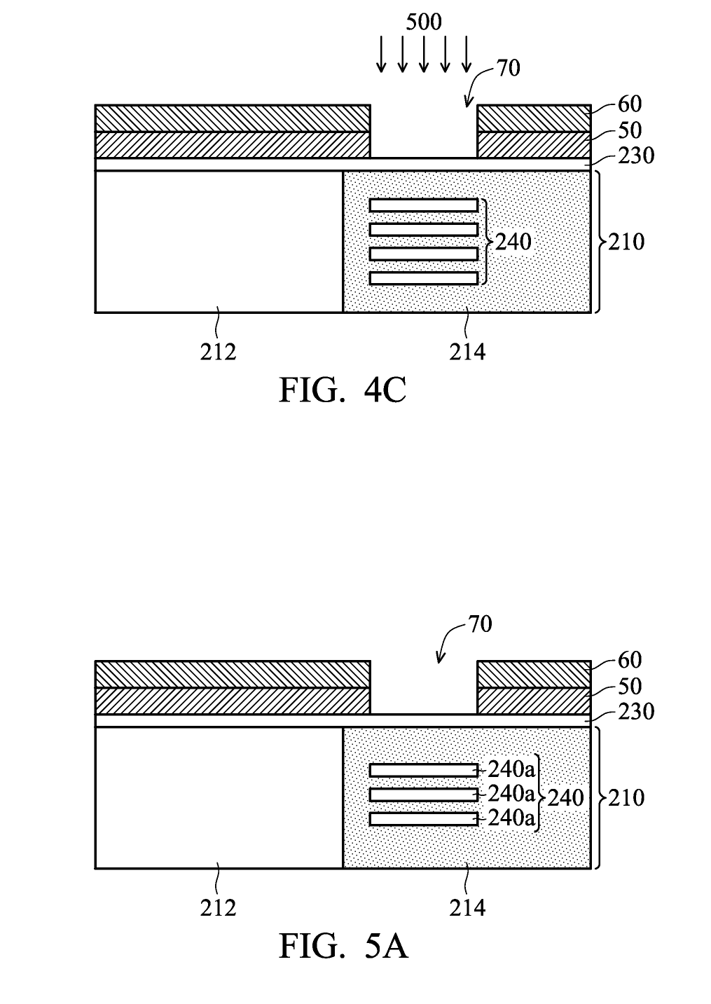

Various configurations of the RESURF structure 240 are illustrated in FIGS. 5a-5b in accordance with exemplary embodiments of the present disclosure. Referring to FIG. 5a, a cross-sectional view of the RESURF structure 240 is illustrated in accordance with an exemplary embodiment of the present disclosure. The RESURF structure 240 is a multi-layered consisting of a series of first type ions 240a in a vertical direction. The first type ions may be n-type or p-type.

Referring to FIG. 5b, in another embodiment, the RESURF structure 240 is formed by alternating a plurality of first type and second type ions 240a and 240b in a vertical direction, wherein the first type ions are opposite to the second type ions.

Although various configurations of the multiple RESURF structure 230 in accordance with embodiments are discussed, it should be understood, however, that the present invention is not limited to the configurations shown in FIGS. 5a-5b. To the contrary, it is intended to cover various modifications and similar arrangements. For example, the number of the ions of the multiple RESURF structure may be more or less than that of the RESURF structures 240 shown in FIGS. 5a-5b and the thickness or size of each ion regions or layers of the multiple RESURF structure may be varied. Additionally, the multiple RESURF structures of FIGS. 5a-5b may also be formed in the drift region 224 of the epitaxial layer as shown in FIG. 3b.

Following the formation of RESURF structure 240, the second mask layer 60 is removed. A process for forming a dielectric layer with a step is then performed.

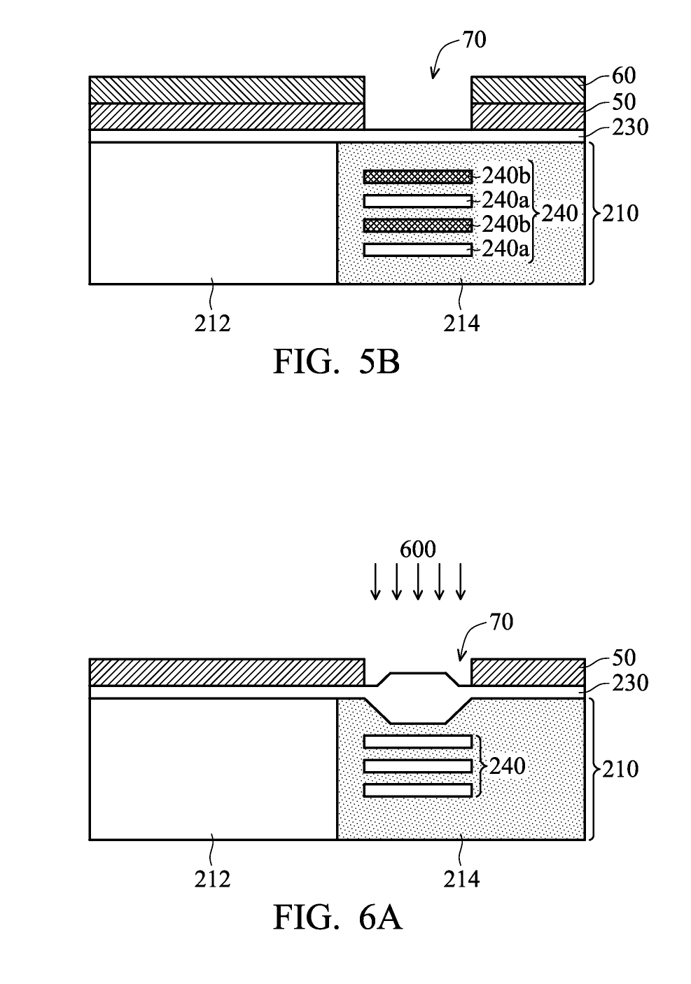

FIGS. 6a-6b illustrate the formation of a multiple dielectric structure 260 in accordance with an exemplary embodiment. It should be realized, the process shown in the following FIGS. 6a-6b may be applied to the structures of FIGS. 5a-5b. Referring to FIG. 6a, a growth process 600 is performed to thicken the portion of the first dielectric layer 230 exposed by the opening 70. The growth process 600 may be thermal oxidation, UV-ozone oxidation, or the like. In some embodiments, a second growth process may be optionally performed to develop a further expansion of the exposed first dielectric layer 230. The expanded portion the first dielectric layer 230 may have a thickness of about 400-8000 angstroms. Referring to FIG. 6b, the first mask layer 50 and a portion of the first dielectric layer 230 is removed, leaving the thick portion of the first dielectric layer 230 and a thin portion adjoining the thick portion of the first dielectric layer 230. The remaining portions of the first dielectric layer 230 are defined as multiple the dielectric layer 260. The thick portion of the multiple dielectric structure 260 defines a step 260a on an edge of the multiple dielectric structure 260. In an embodiment, a portion of the multiple dielectric structure 260 may expand into the substrate 210 (or the epitaxial layer 220 if any), as shown as FIG. 6b. As shown in the figure, the RESURF structure 240 may be aligned with the thick portion of the multiple dielectric structure 260.

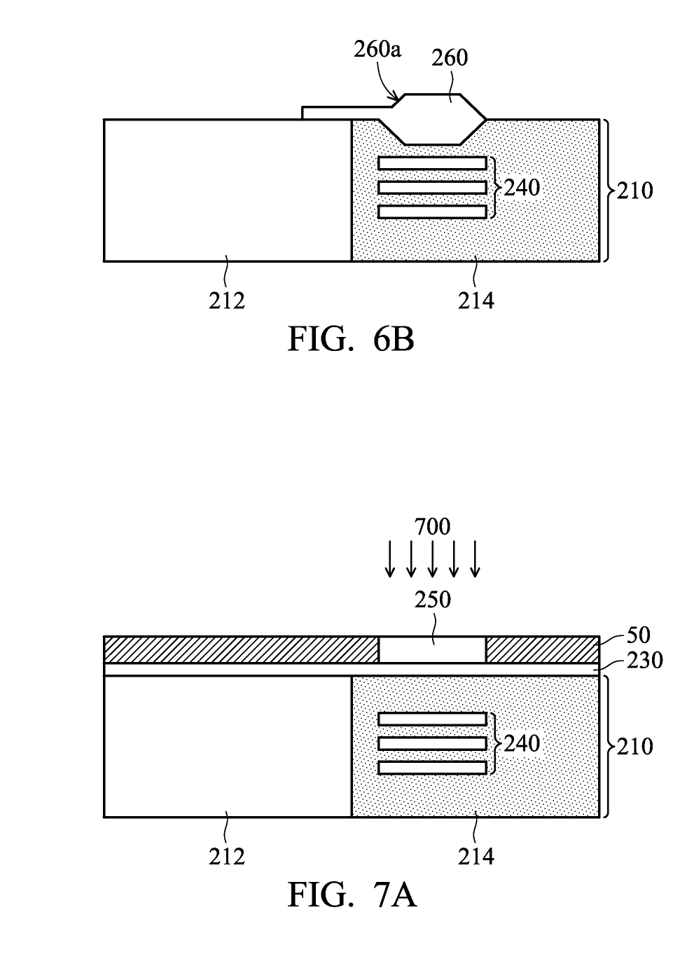

FIGS. 7a-7b illustrate a step-by-step procedure for forming the multiple dielectric structure 260 in accordance with another exemplary embodiment.

Following the steps in FIG. 5b, referring to FIG. 7a, a second dielectric layer 250 is formed in the opening 70 after the second mask layer 60 is removed. The second dielectric layer 250 comprises silicon oxide, silicon nitride, silicon oxynitride, high-k dielectrics, other suitable dielectric materials, or combinations thereof. High-k dielectrics may comprise metal oxides, for example, oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu and mixtures thereof. The second dielectric layer 250 may be formed by a deposition process 700, such as atomic layer deposition (ALD), chemical vapor deposition (CVD), physical vapor deposition (PVD), or the like. A process may be performed to planarize the second dielectric layer 250, such as chemical mechanical polish (CMP). In an embodiment, the second dielectric layer 250 may be thicker than the first dielectric layer 230. The second dielectric layer 250 may be aligned with the RESURF structure 240 as shown in the figures. A removing process, such as etching or the like, is performed to remove the first mask layer 50 and a portion of the first dielectric layer 230, leaving the second dielectric layer 250, and a portion of the first dielectric layer 230 under the second dielectric layer and extending away from an end of the second dielectric layer 250. The remaining first dielectric layer 230 and the second dielectric layer 250 are associated together form the multiple dielectric structure 260. The height difference between the first and the second dielectric layers 230 and 250 defines a step 260a. The thickness of the second dielectric layer 250 may be about 100 angstroms to 5000 angstroms. In an embodiment, the first and second dielectric layers 230 and 250 may be formed of the same material. In another embodiment, the first and second dielectric layers 230 and 250 may be formed of different materials, for example, the first dielectric layer 230 may be silicon dioxide and the second dielectric layer 250 may be silicon nitride or other suitable dielectric materials. Although the step 260a shown in FIGS. 6 and 7 is a cliff-shape, it should be realized that the step 260a may also be in a rounded-shape or any other suitable shapes.

After the multiple dielectric structure 260 of FIG. 6b or FIG. 7b is formed, a thermal oxidation process is applied to the multiple dielectric structure 260. After the thermal oxidation process, the multiple dialectic structure 260 is referred to as gate dielectric layer 260.

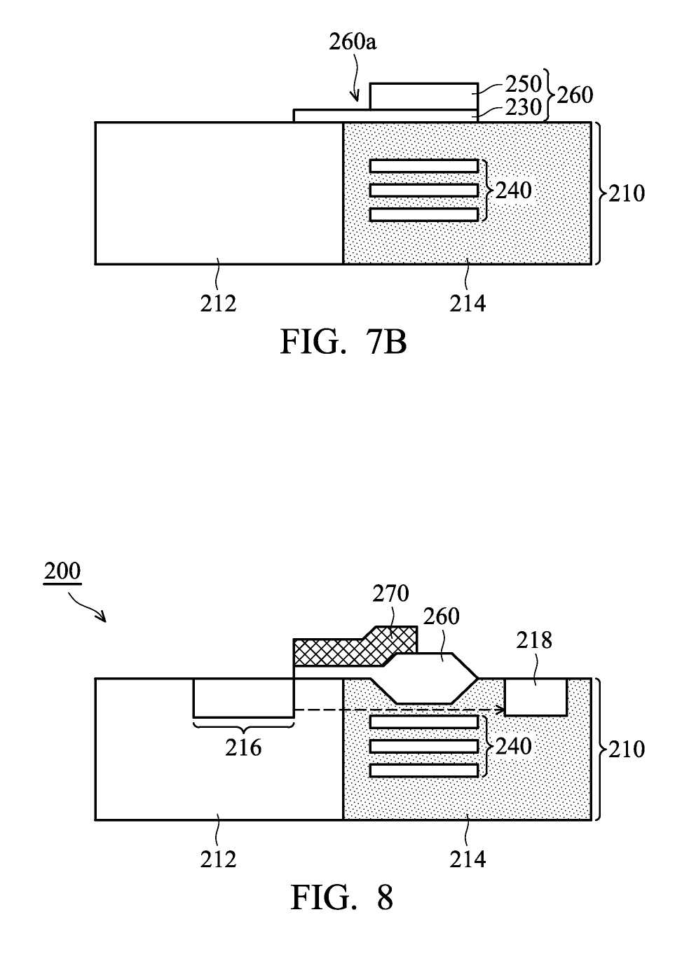

Following the completion of gate dielectric layer 260, source and drain regions are formed. Referring to FIG. 8, a source region 216 is formed in the body region 212 and a drain region 218 is formed in the drift region 214. The source and drain regions 216 and 218 may be formed by a doping process commonly used in the art, such as an ion implantation process.

Still referring to FIG. 8, a gate electrode 270 is formed over the gate dielectric and step dielectric layer 260. The gate electrode 270 may include a single layer or multilayer structure formed on the gate dielectric structure 280. The gate electrode 270 may be formed of a conductive material, such as metal, doped polysilicon, or combinations thereof. The gate electrode 270 may be formed using a process such as low-pressure chemical vapor deposition (LPCVD), plasma enhanced chemical vapor deposition (PECVD), other suitable processes, or combinations thereof.

Features that are commonly found in a conventional semiconductor device such as an inter-layer dielectric (ILD) layer and source/drain electrodes (not shown) may be formed to complete the formation of the semiconductor device 200. The formations of such features are known in the art, and hence will not be discussed herein.

The disclosed embodiments provide at least the following advantages over the conventional LDMOS device. First, the RESURF structure 240 provides a shorter path (as shown as the dotted line in FIG. 8) for the current to flow from the source region 216 to the drain region 218, which may lead to low on-resistance (Rₒₙ) of the semiconductor device 200. Second, due to the design of the step 260a of the gate dielectric layer 260, the breakdown voltage level may be maintained while reducing the on-resistance of the semiconductor device 200. Third, the step 260a at the edge of the gate dielectric layer 260 is formed through the same opening of the mask layer used to define the RESURF region, thus, costs can be reduced since it would not be necessary to employ an extra process and/or mask layer to form the step.

Although the embodiments illustrate specific semiconductor devices; however, it should be understood that the trenched gate electrode that extends into the isolation structure may be applied to other semiconductor devices, such as aDDDMOS, EDMOS, VDMOS, JFET, LIGBT (Lateral Insulated Gate Bipolar Transistor), etc.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate having a first conductivity type, comprising:
a body region having the first conductivity type;
a source region formed in the body region;
a drift region having a second conductivity type adjacent to the body region, wherein the first conductivity type is opposite to the second conductivity type; and
a drain region formed in the drift region;
a multiple reduced surface field (RESURF) structure embedded in the drift region of the substrate; and
a gate dielectric layer having a thick portion formed over the substrate, wherein the gate dielectric comprises at least a stepped-shape or a curved-shape formed thereon, and wherein the multiple RESURF structure is aligned with the thick portion of the gate dielectric layer.

2. The semiconductor device of claim 1, wherein the multiple RESURF structure is a multi-layered structure formed by implanting a series of p-type ions in a vertical direction.

3. The semiconductor device of claim 1, wherein the multiple RESURF structure is a multi-layered structure formed by alternating p-type and n-type ions in a vertical direction.

4. The semiconductor device of claim 1, wherein the body and drift regions are formed in an epitaxial layer of the substrate and the gate dielectric layer is formed over the epitaxial layer of the substrate.

5. The semiconductor device of claim 1, wherein the concentration of the substrate is greater than that of the body region.

6. A method for fabricating a semiconductor device, comprising:
providing a semiconductor substrate having a first conductivity type;
forming a body region having the first conductivity type in the substrate and a drift region having a second conductivity type adjacent to the body region, wherein the first conductivity type is opposite to the second conductivity type;
forming a first dielectric layer over the substrate;
forming a mask layer over the first dielectric layer, wherein the mask layer has an opening exposing a portion of the first dielectric layer;
performing an ion implantation process through the opening to form a multiple reduced surface field (RESURF) structure in the drift region;
forming a second dielectric layer over the portion of the first dielectric layer in the opening, wherein the second dielectric layer is thicker than the first dielectric layer and wherein the multiple RESURF structure is aligned with the second dielectric layer;
removing the mask layer;
removing another portion of the first dielectric layer, wherein the remaining portion of the first dielectric layer associates with the second dielectric layer to form a multiple dielectric structure, wherein the multiple dielectric structure comprises at least a stepped-shape or a curved-shape formed thereon;
applying a thermal oxidation to the multiple dielectric structure to define the multiple dielectric structure as a gate dielectric layer;
forming a source region in the body region and a drain region in the drift region; and
forming a gate electrode over the gate dielectric layer.

7. The method of claim 6, wherein the multiple RESURF structure is a multi-layered structure formed by implanting a series of p-type ions in a vertical direction.

8. The method of claim 6, wherein the multiple RESURF structure is a multi-layered structure formed by alternating p-type and n-type ions in a vertical direction.

9. The method of claim 6, wherein the method for forming the second dielectric layer comprises:
depositing a dielectric material in the opening; and
performing a polishing process to remove the excess portion of the dielectric material.

10. The method of claim 9, wherein the dielectric material is deposited by atomic layer deposition (ALD), chemical vapor deposition (CVD), physical vapor deposition (PVD), or combinations thereof.

11. The method of claim 6, wherein the method for forming the second dielectric layer comprises:
applying an oxidation process to the portion of the first dielectric layer in the opening such that the portion of the first dielectric layer expands to a greater thickness thereby defining the second dielectric layer, wherein the second dielectric layer extends from the surface of the substrate into the substrate.

12. The method of claim 11, wherein the oxidation process comprises thermal oxidation, UV-ozone oxidation, or combinations thereof.

13. The method of claim 6, wherein the gate dielectric layer comprises silicon oxide, nitrogen oxide, carbon oxide, silicon oxynitride, or combinations thereof.

14. The method of claim 6, wherein the first mask layer is a silicon nitride hard mask or a silicon oxynitride hard mask, and the second mask layer is a patterned photoresist.

15. The method of claim 6, wherein the first conductivity type is p-type and the second conductivity type is n-type.

16. The method of claim 7, further comprising:
forming an epitaxial layer in the substrate, wherein the body and drift regions are formed in an epitaxial layer of the substrate and the gate dielectric layer is formed over the epitaxial layer of the substrate.
